(19) United States
(12) Patent Application Publication
(10) Pub. No.: US 2025/0277312 A1
(43) Pub. Date: Sep. 4, 2025

(54) SACRIFICIAL LINER FOR COPPER INTERCONNECT

(71) Applicant: Applied Materials, Inc., Santa Clara, CA (US)

(72) Inventors: Zhiyuan WU, San Jose, CA (US); Kevin KASHEFI, Dublin, CA (US)

(21) Appl. No.: 18/593,610

(22) Filed: Mar. 1, 2024

(51) Int. Cl. C23C 28/02; C23C 14/02; C23C 14/58

(52) U.S. Cl. CPC C23C 28/023; C23C 14/021; C23C 14/588

(57) ABSTRACT

A method and apparatus for forming an interconnect structure. The method includes depositing a ruthenium layer on a cobalt layer disposed within a feature formed on a substrate. The ruthenium layer has a ruthenium concentration that increases from a lower portion of the feature to an upper portion of the feature. The method includes depositing a copper layer within the feature. A material forming the copper layer is heated to a reflow temperature before, during, or after depositing the copper layer.

### BACKGROUND

### Field

Embodiments of this disclosure relate to an apparatus and a method of depositing layers on a substrate.

### Description of the Related Art

Integrated circuits may include more than one million micro-electronic field effect transistors (e.g., complementary metal-oxide-semiconductor (CMOS) field effect transistors) that are formed on a substrate (e.g., semiconductor wafer) and cooperate to perform various functions within the circuit. Reliably producing smaller features is one of the key technologies for the next generation of very large scale integration (VLSI) and ultra large-scale integration (ULSI) of semiconductor devices. However, as the limits of integrated circuit technology are pushed, the shrinking dimensions of interconnects in VLSI and ULSI technology have placed additional demands on processing capabilities. Reliable formation of the gate pattern is important to integrated circuits success and to the continued effort to increase circuit density and quality of individual substrates and dies.

Conventional methods of deposition have issues depositing materials in critical dimension (CD) openings associated with VLSI and ULSI technology (e.g., less than about 12 nm) due to pinch off of the deposited films. Resputter efficiency inside the structure is reduced during physical vapor deposition (PVD) processing, which often has an unacceptable thickness profile within the feature. Poor step coverage, overhang, and voids can be formed within features, such as vias or trenches, when the feature has a CD of less than about 12 nm. Insufficient deposition on the bottom and side walls of the vias or trenches can also result in deposition discontinuity, thereby resulting in device open circuitry or poor interconnection formation. Furthermore, the metal layer may have poor adhesion over the underlying material layer, resulting in peeling of the metal layer from the substrate and the subsequent conductive metal layer.

Therefore, there is a need for an apparatus and a method of depositing metal layers in small width critical dimension features with acceptable thickness profiles.

### SUMMARY

The present disclosure generally relates to methods for forming an interconnect structure. In one embodiment, a method includes depositing a ruthenium layer on a cobalt layer disposed within a feature formed on a substrate. The ruthenium layer has a ruthenium concentration that increases from a lower portion of the feature to an upper portion of the feature. The method includes depositing a copper layer within the feature. A material forming the copper layer is heated to a reflow temperature before, during, or after depositing the copper layer.

In another embodiment, a method includes depositing a cobalt layer on a barrier layer, the barrier layer being disposed within a feature. The method includes depositing a ruthenium layer on the cobalt layer disposed within the feature. The ruthenium layer has a ruthenium concentration that substantially increases from a lower portion of the feature to an upper portion of the feature. The method includes depositing a copper layer within the feature. A material forming the copper layer is heated to a reflow temperature before, during, or after depositing the copper layer.

In yet another embodiment, a method includes depositing a ruthenium layer on a cobalt layer disposed within a feature. The ruthenium layer has a ruthenium concentration that increases from a lower portion of the feature to an upper portion of the feature. The method includes depositing a copper layer within the feature. A material forming the copper layer is heated to a reflow temperature before, during, or after depositing the copper layer. The method includes removing a top portion of the interconnect structure. The top portion of the interconnect structure comprises a first portion of the ruthenium layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A illustrates a schematic side view of a processing chamber, according to at least one embodiment.

FIG. 1B illustrates a schematic side view of a physical vapor deposition (PVD) processing chamber, according to at least one embodiment.

FIG. 2 illustrates a schematic top view of a multi-chamber processing system, according to at least one embodiment.

FIG. 3 is a flow diagram of method operations for depositing a plurality of layers, according to at least one embodiment.

FIGS. 4A-4D illustrate a schematic side view of a device structure during various operations of the method of FIG. 3, according to at least one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to methods of depositing a plurality of layers on a patterned substrate that contains features. A cobalt (Co) layer is deposited using a chemical vapor deposition (CVD) process in a plurality of feature definitions in a device structure formed on a substrate. In some embodiments of the method described herein, a ruthenium (Ru) layer is deposited over a cobalt (Co) containing layer that is formed in the plurality of feature definitions of the device structure using a physical layer deposition (PVD) process. One or more copper layers can then be deposited over the ruthenium layer, and the copper layers can be reflowed to create a copper layer that has a desired thickness profile. The Ru layer deposited over the Co layer may encourage increased flowability, reducing poor step coverage, overhang, and voids in the formed copper layer. The desired thickness profile increases device yield, reliability of the device structure, reducing device open circuitry and improving interconnection formation. Furthermore, thickness reduction associated with achieving the desired thickness profile can allow deposition processes to be extended to higher aspect ratio applications. Embodiments disclosed herein may be useful for, but are not limited to, increasing the flowability of deposited copper layers using dopants, such as Ru, Co.

As used herein, the term “about” refers to a +/−10% variation from the nominal value. It is to be understood that such a variation can be included in any value provided herein.

### Processing System Examples

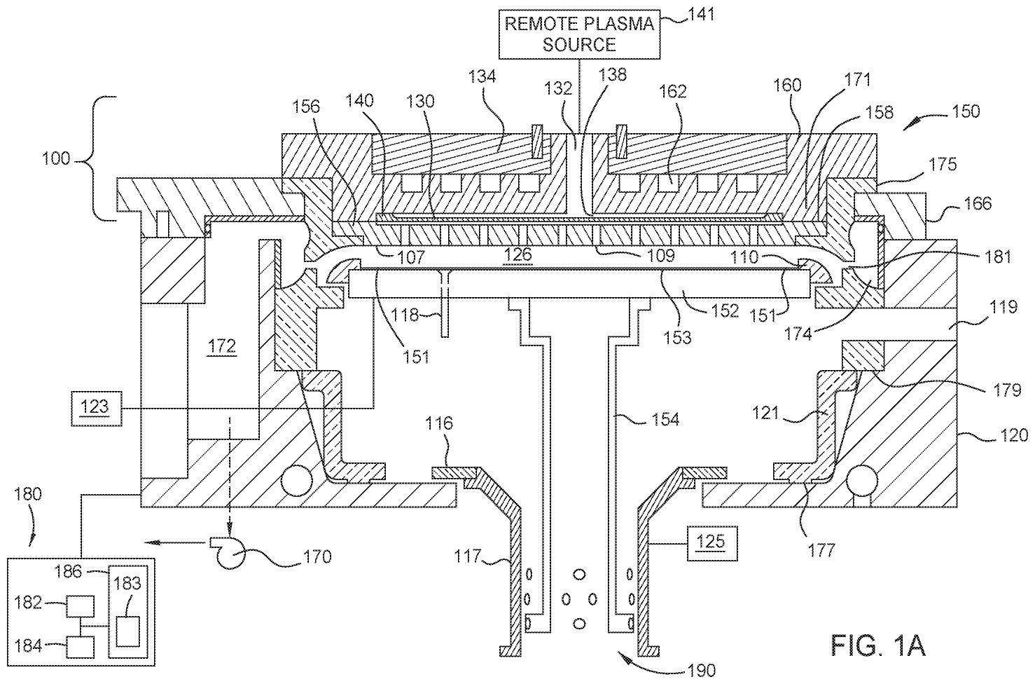

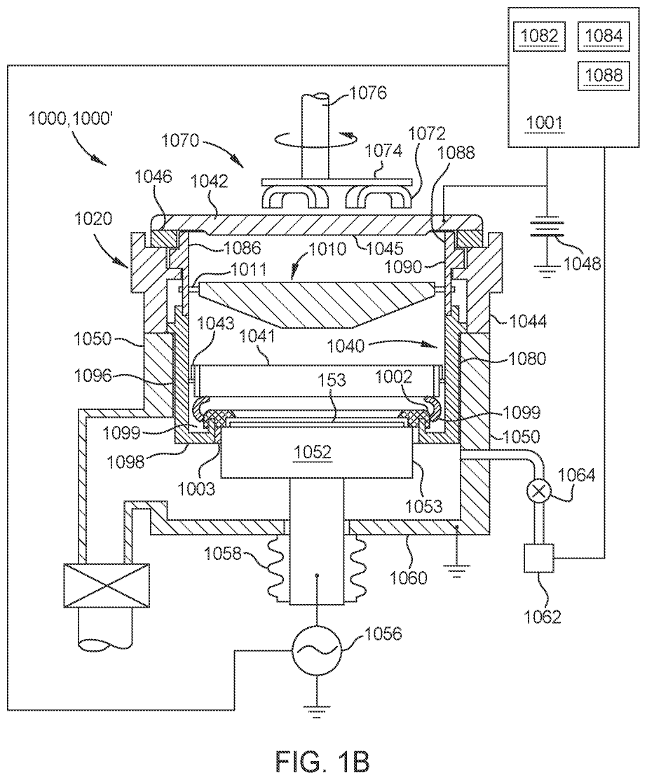

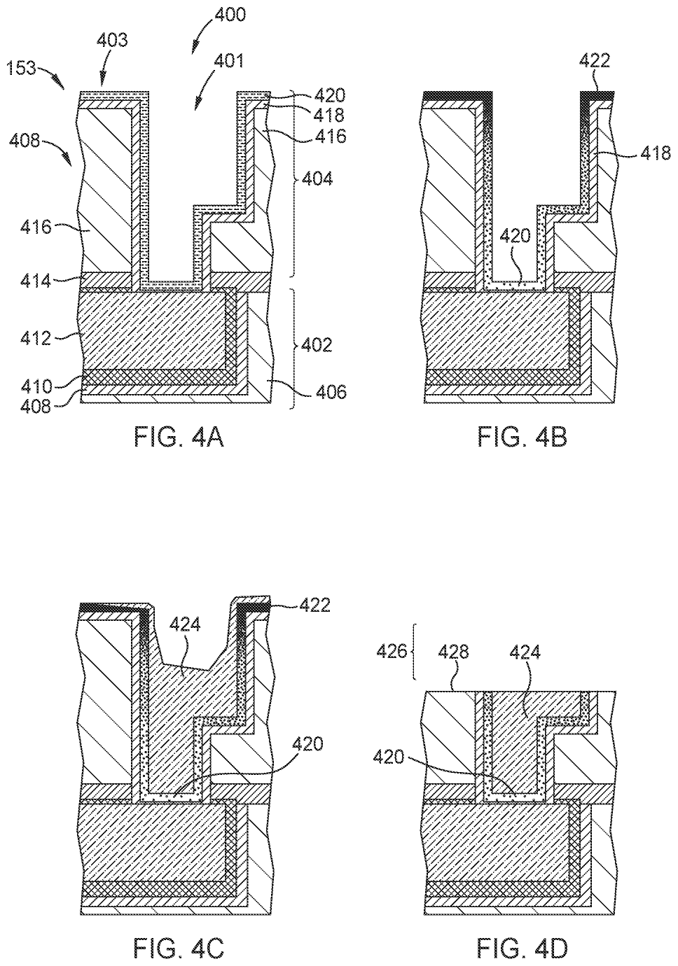

FIG. 1A illustrates a schematic side view of a processing chamber 150, according to at least one embodiment. The processing chamber 150 is configured to deposit a variety of materials, such as metal materials, onto interconnect structures 400 (FIG. 4) formed on a substrate 153 disposed within the processing chamber. As shown, the processing chamber 150 includes a pedestal assembly 190, a lid assembly 100, a chamber body 120, and a control unit 180. The chamber body 120 is configured to protect substrates disposed within the body from the environment outside the body. Metal materials that can be deposited in the processing chamber 150 can include cobalt (Co), copper (Cu), nickel (Ni), ruthenium (Ru), derivatives thereof, or combinations thereof. The processing chamber 150 can be used to perform CVD, plasma enhanced-CVD (PE-CVD), pulsed-CVD, ALD, PE-ALD, derivatives thereof, or combinations thereof. The processing chamber 150 can also be used to anneal previously deposited metal layers. Thus, both the deposition processes and the subsequent annealing may be performed in-situ in the same processing chamber 150. In other embodiments, deposition of material and annealing of material can be performed in separate chambers.

As shown, the lid assembly 100 includes a showerhead 156 with holes 109, a blocker plate 140, a water cooling cover plate 134, a convolute liquid channel 162, a gas box plate 160, and a lid isolator 175. The lid assembly 100 is configured to deliver gas through the holes 109 onto the substrate 153 disposed on a substrate supporting surface of a heater pedestal 152, which is disposed below the showerhead 156. Water channels, such as a convolute liquid channel 162, are used to regulate the temperature of the lid assembly 100 during the vapor deposition process for depositing material. The lid assembly 100 is heated or maintained at a temperature within a range from about 100° C. to about 300° C., such as from about 125° C. to about 225° C., or from about 150° C. to about 200° C., according to at least one embodiment. The temperature can be maintained during the vapor deposition process of a cobalt-containing material, nickel containing material, or copper-containing material.

The showerhead 156 has a relatively short upwardly extending rim 158 coupled with the gas box plate 160. Both the showerhead 156 and the gas box plate 160 can be formed from or contain a metal, such as aluminum, stainless steel, or alloys thereof. The convolute liquid channel 162 is formed in the top of the gas box plate 160 and covered and sealed by the water cooling cover plate 134. Water is generally flown through the convolute liquid channel 162. In one example, the lid assembly 100 is configured to be heated or maintained at a temperature of about 150° C. and is in fluid communication with a source of a cobalt precursor, such as dicobalt hexacarbonyl butylacetylene (C12H10O6Co) (CCTBA), and a source of a hydrogen precursor, such as hydrogen gas (H2).

The showerhead 156 has a plurality of apertures or holes 109 communicating between the lower cavity 130 and a processing region 126 to allow for the passage of processing gas. The processing gas is supplied through a gas port 132 formed at the center of the gas box plate 160 which is made of aluminum and is water-cooled. The upper side of the gas box plate 160 is covered by the water cooling cover plate 134 surrounding the upper portion of the gas box plate 160 that includes the gas port 132. The gas port 132 supplies the processing gases to an upper cavity 138 which is separated from the lower cavity 130 by a blocker plate 140. The blocker plate 140 has a large number of holes 109 disposed therethrough. In one implementation, the cavities 130 and 138, showerhead 156, and blocker plate 140 evenly distribute the processing gas over the upper face of the substrate 153.

The pedestal assembly 190 is configured to support a substrate 153 that includes interconnect structures 400 during processing of the substrate. As shown, the pedestal assembly 190 includes a heater pedestal 152, a pedestal stem 154, lift pins 118, a lifting ring 116, and a lift tube 117. The heater pedestal 152 is connected to the pedestal stem 154 that may be vertically moved within the processing chamber 150. The heater portion of the heater pedestal 152 can be formed of a ceramic material. In its upper deposition position, the heater pedestal 152 holds a interconnect structures 400 in close opposition to a lower surface 107 of the showerhead 156. A processing region 126 is defined between the heater pedestal 152 and the lower surface 107 of the showerhead 156.

The substrate 153 is supported on the heater pedestal 152, which is illustrated in a raised, deposition position. In a lowered, loading position, the lifting ring 116 is attached to the lift tube 117 which lifts four lift pins 118. The lift pins 118 fit to slide into the heater pedestal 152 so that the lift pins 118 can receive the substrate 153 loaded into the chamber through a loadlock port 119 in the chamber body 120. The heater pedestal 152 can additionally include a confinement ring 110 for plasma-enhanced vapor deposition processes.

A side purge gas source 123 can be coupled to the processing chamber 150 and configured to supply purge gas to an edge portion 151 of the interconnect structures 400 as needed. The purge gas can include H₂, argon gas (Ar), nitrogen gas (N₂), helium gas (He), combinations thereof, or the like. Furthermore, a bottom purge gas source 125 can also be coupled to the processing chamber 150 to supply the purge gas from the bottom of the processing chamber 150 to the substrate surface. Similarly, the purge gas supplied from the bottom purge gas source 125 can include a H₂, Ar, N₂, He, combinations thereof, or the like.

The lid isolator 175 is interposed between the showerhead 156 and a lid rim 166, which can be lifted off the chamber body 120 to open the processing chamber 150 for maintenance access. The vacuum within the processing chamber 150 is maintained by a vacuum pump 170 connected to a pump plenum 172 within the processing chamber 150, which connects to an annular pumping channel 174.

A chamber liner 179 made of quartz is disposed in the processing chamber 150 which defines a side of the annular pumping channel 174, but also partially defines a further choke aperture 181 disposed between the processing region 126 and the annular pumping channel 174. The chamber liner 179 can have an annular shape. The chamber liner 179 also supports the confinement ring 110 in the lowered position of the heater pedestal 152. The chamber liner 179 also surrounds a circumference at the back of the heater pedestal 152. The chamber liner 179 rests on a narrow ledge in chamber body 120, but there is little other contact, so as to minimize thermal transport. Below the chamber liner 179 is located a lower chamber shield 121, made of opaque quartz. The lower chamber shield 121 can be a z-shaped chamber shield. The lower chamber shield 121 rests on the bottom of the chamber body 120 on an annular boss 177 formed on the bottom of the lower chamber shield 121. The quartz prevents radiative coupling between the bottom of the heater pedestal 152 and the chamber body 120. The annular boss 177 minimizes conductive heat transfer to the chamber body 120. The lower chamber shield 121 includes an inwardly extending bottom lip joined to a conically shaped upper portion conforming to the inner wall of chamber body 120, according to some embodiments.

A remote plasma source 141 is coupled to the processing chamber 150 through a gas port 132 to supply reactive plasma from the remote plasma source 141 through the plurality of holes 109 in the showerhead 156 to the processing chamber 150 to the substrate surface. It is noted that the remote plasma source 141 may be coupled to the processing chamber 150 in any suitable position to supply a reactive remote plasma source to the substrate surface as needed. Suitable gases that may be supplied to the remote plasma source 141 to be dissociated and further delivered to the substrate surface include H₂, N₂, Ar, He, ammonia (NH₃), combinations thereof, and the like.

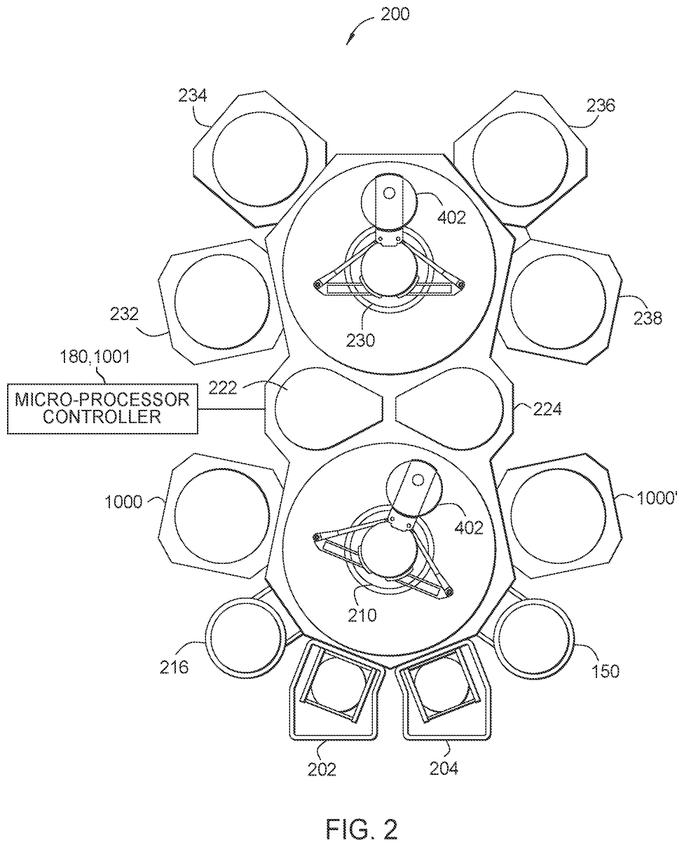

The control unit 180 is configured to control the various components of the processing chamber 150. The control unit can be one of any form of a general purpose computer processor that can be used in an industrial setting for controlling various chambers and sub-processors. As shown, the control unit 180 includes one or more central processing units (CPUs) 182, support circuitry 184, and memory 186. The CPUs can be configured within the control unit 180 to operate in sequence with one another or to operate in parallel with one another, and may communicate with one another via a message passing interface (not shown). The CPUs 182 can use any suitable memory 186, such as random access memory, read only memory, floppy disk drive, compact disc drive, hard disk, or any other form of digital storage, local or remote. Various support circuits may be coupled to the CPUs 182 for supporting the processing chamber 150. The control unit 180 can be coupled to another controller that is located adjacent individual chamber components. Bi-directional communications between the control unit 180 and various other components of the processing chamber 150 are handled through numerous signal cables collectively referred to as signal buses. The control unit 180 can also be configured to control various chambers of a multi-chamber processing system 200 as described below in FIG. 2.

FIG. 1B illustrates a processing chamber 1000, according to at least one embodiment. The processing chamber 1000 is configured to sputter material onto a substrate. The processing chamber 1000 is a physical vapor deposition (PVD) chamber, capable of depositing, for example, ruthenium, titanium, cobalt, aluminum oxide, aluminum, copper, tantalum, tantalum nitride, tungsten, or tungsten nitride on a substrate, according to at least one embodiment. Examples of suitable PVD chambers include the ALPS® Plus and SIP ENCORE® PVD processing chambers, both commercially available from Applied Materials, Inc., Santa Clara, of Calif. It is contemplated that processing chambers available from other manufactures may also be utilized to perform the embodiments described herein. As shown, the processing chamber 1000 includes a target 1042, a substrate support pedestal 1052, a magnetron 1070, a process kit 1040, a control unit 1001, and a body 1020.

The target 1042 is configured to deposit material on the interconnect structures 400 (FIG. 4) formed on a substrate 153. As shown, the target 1042 has a sputtering surface 1045. The target 1042 is supported by a grounded adapter 1044 through a dielectric isolator 1046. The target 1042 includes the material to be deposited on the substrate 1054 surface during sputtering, and can include copper for depositing as a seed layer in high aspect ratio features formed in the interconnect structures 400. The target 1042 also includes a bonded composite of a metallic surface layer of sputterable material, such as copper, and a backing layer of a structural material, such as aluminum, according to at least one embodiment. The target 1042 can also include other materials, such as Ru, Co, Ta, Nb, V, Cu, or manganese (Mn).

The substrate support pedestal 1052 is configured to support a substrate 153. As shown, the substrate support pedestal 1052 has a peripheral edge 1053. The substrate support pedestal 1052 can be located within a grounded chamber wall 1050. The substrate support pedestal 1052 supports the substrate 153 having high aspect ratio features to be sputter coated, the bottoms of which are in planar opposition to a principal surface of the target 1042. The substrate support pedestal 1052 has a planar substrate-receiving surface disposed generally parallel to the sputtering surface of the target 1042. The substrate support pedestal 1052 can be vertically movable through a bellows 1058 connected to a bottom wall 1060 of the processing chamber 1000 to allow the interconnect structures 400 to be transferred onto the substrate support pedestal 1052 through a load lock valve (not shown) in a lower portion of the processing chamber 1000. The substrate support pedestal 1052 can then be raised to a deposition position, as illustrated in FIG. 1B.

Processing gas can be supplied from a gas source 1062 through a mass flow controller 1064 into the lower portion of the processing chamber 1000. A direct current (DC) power source 1048, coupled to the processing chamber 1000, is used to apply a negative voltage or bias to the target 1042, according to at least one embodiment. A radio frequency (RF) power source 1056 can be coupled to the substrate support pedestal 1052 to induce a DC self-bias on the substrate 153. The substrate support pedestal 1052 is grounded, according to at least one embodiment. The substrate support pedestal 1052 is electrically floated, according to at least one embodiment.

The magnetron 1070 is configured to provide a magnetic field to the target 1042 to sputter material of the target onto the substrate 153 below. As shown, the magnetron 1070 includes a plurality of magnets 1072, a base plate 1074, and a shaft 1076. The magnetron 1070 is positioned above the target 1042. The plurality of magnets 1072 is supported by the base plate 1074 connected to the shaft 1076, which may be axially aligned with the central axis of the processing chamber 1000 and the substrate 153. The plurality of magnets 1072 are aligned in a kidney-shaped pattern, according to at least one embodiment. The plurality of magnets 1072 produce a magnetic field within the processing chamber 1000 near the front face of the target 1042 to generate plasma, such that a significant flux of ions strike the target 1042, causing sputter emission of target material. The plurality of magnets 1072 can be rotated about the shaft 1076 to increase uniformity of the magnetic field across the surface of the target 1042. The magnetron 1070 can be a small magnet magnetron. The magnets 1072 can be both rotated and moved reciprocally in a linear direction substantially parallel to the face of the target 1042 to produce a spiral motion. The magnets 1072 can be rotated about both a central axis and an independently-controlled secondary axis to control both their radial and angular positions.

The process kit 1040 is configured to protect various components of the processing chamber 1000 from unwanted sputtering from the target 1042. As shown, the process kit 1040 includes a lower shield 1080, a one-piece upper shield 1086, and an optional collimator 1010. The lower shield 1080 has a support flange supported by and electrically coupled to the chamber wall 1050. The lower shield 1080 can include multiple pieces, or the lower shield can be one piece. The lower shield 1080 can be grounded. The upper shield 1086 is supported by and electrically coupled to a flange of the adapter 1044. The upper shield 1086 and the lower shield 1080 are electrically coupled, as are the adapter 1044 and the chamber wall 1050. Both the upper shield 1086 and the lower shield 1080 can include stainless steel. The processing chamber 1000 can include a middle shield (not shown) coupled to the upper shield 1086. In one embodiment, the upper shield 1086 and the lower shield 1080 are electrically floating within the processing chamber 1000. In one embodiment, the upper shield 1086 and the lower shield 1080 are coupled to an electrical power source.

In one embodiment, the upper shield 1086 has an upper portion that closely fits an annular side recess of the target 1042 with a narrow gap 1085 between the upper shield 1086 and the target 1042, which is sufficiently narrow to prevent plasma from penetrating and sputter coating the dielectric isolator 1046. The upper shield 1086 may also include a downwardly projecting tip 1090, which covers the interface between the lower shield 1080 and the upper shield 1086, preventing them from being bonded by sputter deposited material.

The lower shield 1080 extends downwardly into a cylindrical outer band 1096, which generally extends along the chamber wall 1050 to below the top surface of the substrate support pedestal 1052. The lower shield 1080 has a base plate 1098 extending radially inward from the cylindrical outer band 1096. The base plate 1098 includes an upwardly extending cylindrical inner band 1003 surrounding the perimeter of the substrate support pedestal 1052. A cover ring 1002 rests on the top of the cylindrical inner band 1003 when the substrate support pedestal 1052 is in a lower/loading position and rests on the outer periphery of the substrate support pedestal 1052 when the pedestal is in an upper/deposition position to protect the substrate support pedestal 1052 from sputter deposition.

The lower shield 1080 encircles the sputtering surface 1045 of the target 1042 that faces the substrate support pedestal 1052 and also encircles a peripheral wall of the substrate support pedestal 1052. The lower shield 1080 covers and shadows the chamber wall 1050 of the processing chamber 1000 to reduce deposition of sputtering deposits originating from the sputtering surface 1045 of the target 1042 onto the components and surfaces behind the lower shield 1080. For example, the lower shield 1080 can protect the surfaces of the substrate support pedestal 1052, portions of the substrate 153, the chamber wall 1050, and the bottom wall 1060 of the processing chamber 1000.

The collimator 1010 is configured to trap metal ions and neutrals that are emitted from the target 1042 at angles exceeding a selected angle, near normal to the substrate 153. Directional sputtering is achieved by positioning the collimator 1010 between the target 1042 and the substrate support pedestal 1052. The collimator 1010 is mechanically and electrically coupled to the upper shield 1086. The collimator 1010 is attached to the upper shield 1086 by a plurality of radial brackets 1011. In one embodiment, the collimator 1010 is coupled to a middle shield (not shown), positioned lower in the processing chamber 1000. In one embodiment, the collimator 1010 is integral to the upper shield 1086. In one embodiment, the collimator 1010 is welded to the upper shield 1086. In one embodiment, the collimator 1100 is electrically floating within the processing chamber 1000. In one embodiment, the collimator 1010 is coupled to an electrical power source. The collimator 1010 includes a plurality of apertures (omitted from FIG. 1) to direct gas and/or material flux within the chamber. The operation of the processing chamber 1000 and the function of the collimator 1010 are similar regardless of the exact shape of the radial decreasing aspect ratio of the collimator 1010.

The control unit 1001 is configured to control the various components of the processing chamber 1000. The control unit 1001 can be one of any form of a general purpose computer processor that can be used in an industrial setting for controlling various chambers and sub-processors. As shown, the control unit 1001 includes a central processing unit (CPU) 1082, support circuitry 1084, and memory 1088. The CPU 1082 can use any suitable memory 1088, such as random access memory, read only memory, floppy disk drive, compact disc drive, hard disk, or any other form of digital storage, local or remote. Various support circuits may be coupled to the CPU 1082 for supporting the processing chamber 1000. The control unit 1001 can be coupled to another controller that is located adjacent individual chamber components. Bi-directional communications between the control unit 1001 and various other components of the processing chamber 1000 are handled through numerous signal cables collectively referred to as signal buses. The control unit 1001 can also be configured to control various chambers of a multi-chamber processing system 200 as described below in FIG. 2. The control unit 1001 can also control the processing chamber 150 described above.

In one embodiment, the control unit 1001 provides signals to position the substrate 153 on the substrate support pedestal 1052 and generate plasma in the processing chamber 1000. The control unit 1001 sends signals to apply a voltage via the DC power source 1048 to bias the target 1042 and to excite processing gas, such as argon, into plasma. The control unit 1001 further provides signals to cause the RF power source 1056 to DC self-bias the substrate support pedestal 1052. The DC self-bias attracts positively charged ions created in the plasma deeply into high aspect ratio vias and trenches on the surface of the substrate 153.

Additionally, in order to provide even greater coverage of sputter deposited material onto the bottom and side walls of high aspect ratio features, material sputter deposited onto the field and bottom regions of features may be sputter etched. In one embodiment, the control unit 1001 applies a high bias to the substrate support pedestal 1052 such that the target 1042 ions etch film already deposited on the substrate 1054. As a result, the field deposition rate onto the substrate 1054 is reduced, and the sputtered material re-deposits on either the side walls or bottom of the high aspect ratio features. In one embodiment, the control unit 1001 applies high and low bias to the substrate support pedestal 1052 in a pulsing, or alternating fashion such that the process becomes a pulsing deposit/etch process. In one embodiment, the collimator 1010 cells specifically located below magnets 1072 direct the majority of the deposition material toward the substrate 1054. Therefore, at any particular time, material in one region of the substrate 153 is deposited, while material already deposited in another region of the substrate 153 is etched. In one non-limiting example, a Co material can be etched while a Ru material is deposited (e.g., at same time) without increasing liner overhang on top part of the interconnect 400.

In one embodiment, to provide even greater coverage of sputter deposited material onto the side walls of high aspect ratio features, material sputter deposited onto the bottom of the features may be sputter etched using secondary plasma, such as argon plasma, generated in a region of the processing chamber 1000 near the substrate 153. The processing chamber 1000 includes a coil 1041 attached to the lower shield 1080 by a plurality of coil standoffs 1043, which electrically insulate the coil 1041 from the lower shield 1080. The control unit 1001 sends signals to apply RF power through the shield 1080 to the coil 1041 via feedthrough standoffs (not shown). In one embodiment, the coil 1041 inductively couples RF energy into the interior of the processing chamber 1000 to ionize precursor gas, such as argon, to maintain secondary plasma near the substrate 1054. The secondary plasma resputters a deposition layer from the bottom of a high aspect ratio feature and redeposits the material onto the side walls of the feature. The coil 1041 can include any metal, including Cu, Co, Ru, Ta, V, Nb, or combinations thereof.

In addition, in some embodiments, the processing chamber 1000 includes one or more lamps 1099. The one or more lamps 1099 provide heat to the substrate 153. In these embodiments, the processing chamber is identified by the index 1000′.

FIG. 2 illustrates a schematic top view of a multi-chamber processing system 200, according to at least one embodiment. The multi-chamber processing system is configured to perform deposition processes as disclosed herein having a processing chamber 150, 1000, 1000′ as described above in reference to FIGS. 1A-1B, integrated therewith. As shown, the multi-chamber processing system 200 includes load lock chambers 202, 204, processing chambers 1000, 1000′, 150, 216, 232, 234, 236, 238, robots 210, 230, and transfer chambers 222, 224.

The load lock chambers 202, 204 are configured to transfer substrate 153 into and out of the multi-chamber processing system 200. Generally, the multi-chamber processing system 200 is maintained under vacuum and the load lock chambers 202 and 204 can be “pumped down” to introduce substrate 153 introduced into the multi-chamber processing system 200. The first robot 210 transfers the substrate 153 between the load lock chambers 202 and 204, and a first set of one or more processing chambers 1000, 1000′, 216, and 150. Each processing chamber 1000, 1000′, 216, and 150 is configured to be at least one of a substrate deposition process, such as cyclical layer deposition (CLD), atomic layer deposition (ALD), chemical vapor deposition (CVD), physical vapor deposition (PVD), etch, degas, pre-cleaning orientation, anneal, electrochemical plating (ECP), and other substrate processes. Furthermore, one of the processing chambers 1000, 1000′, 216, and 150 can be configured to perform a pre-clean process prior to performing a deposition process or a thermal annealing process on the substrate 153. The position of the processing chamber 150 relative to the other processing chambers 1000, 1000′, and 216 is for illustration, and the position of the processing chamber 150 can optionally be switched with any one of the processing chambers 1000, 1000′, and 216 if desired.

The first robot 210 can also transfer the substrate 153 to/from one or more transfer chambers 222 and 224. The transfer chambers 222 and 224 can be used to maintain ultrahigh vacuum conditions while allowing substrate 153 to be transferred within the multi-chamber processing system 200. A second robot 230 can transfer the substrate 153 between the transfer chambers 222 and 224 and a second set of one or more processing chambers 232, 234, 236 and 238. Similar to the processing chambers 1000, 1000′, 216, and 150, the processing chambers 232, 234, 236, and 238 can be outfitted to perform a variety of substrate processing operations including the dry etch processes described herein in addition to cyclical layer deposition (CLD), atomic layer deposition (ALD), chemical vapor deposition (CVD), physical vapor deposition (PVD), etch, pre-clean, degas, and orientation, for example. Any of the processing chambers 1000, 1000′, 216, 232, 234, 236, and 238 can be removed from the multi-chamber processing system 200 if not necessary for a particular process to be performed by the multi-chamber processing system 200. After the preclean, deposition and/or a thermal annealing process is performed in the processing chamber 150, the substrate may further be transferred to any of the processing chambers 1000, 1000′, 216, 232, 234, 236, and 238 of the system 200 to perform other process as needed.

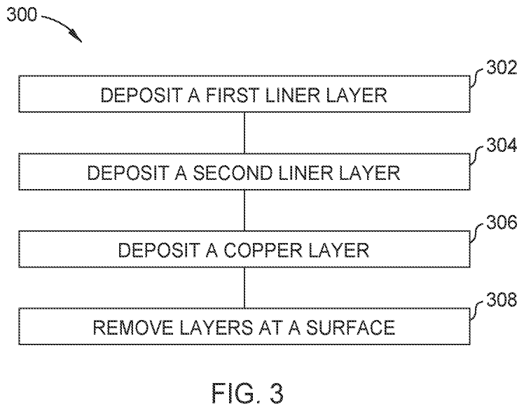

FIG. 3 is a flow diagram of method 300 operations for depositing a plurality of layers in a device structure 409 (FIG. 4A) that includes an interconnect structure 400 formed on a substrate 153, according to at least one embodiment. FIGS. 4A-4D illustrate a schematic side view of a device structure 409 during various operations of the method 300 of FIG. 3, according to at least one embodiment. The plurality of layers can include any of the layers deposited as described in the method 300 below. Although the method 300 operations are described in conjunction with FIGS. 3 and 4A-4D, persons skilled in the art will understand that any system configured to perform the method operations, in any order, falls within the scope of the embodiments described herein. Any of the method 300 operations can be performed in any of the chambers of the multi-chamber processing system 200, such as processing chamber 150, 1000, 1000′, or in any other suitable chamber. In addition, different operations of the method 300 can be performed in different chambers within the multi-chamber processing system 200, or in any other suitable chamber.

### Deposition Process Sequence

FIG. 3 depicts a process flow diagram of a method 300 according to one or more embodiments of the disclosure. FIGS. 4A-4D illustrate cross-sectional schematic views of an interconnect structure 400 during a process method 300 in accordance with one or more embodiments of the disclosure. It should be understood that FIG. 4A-4D illustrate only partial schematic views of interconnect structure 400, and the interconnect structure may contain any number of features and additional materials having aspects illustrated in the figures. It should also be noted that although the method 300 illustrated in FIG. 3 is described sequentially, other process sequences that include one or more operations that have been omitted and/or added, and/or have been rearranged in another desirable order, fall within the scope of the embodiments of the disclosure provided herein.

The interconnect structure 400 may include a first portion (“L1”) 402 and a second portion (“L2”) 404. As illustrated in FIG. 4A, the first portion 402 may be disposed substantially below second portion 404, with a bottom surface 405 of second portion being coupled to first portion 402. The bottom surface 405 of second portion 404 may include vertical surfaces 407 associated with a trench 401 and may extend below some portions of a top surface 403 of first portion 402. The first portion 402 may include a dielectric layer 406, a barrier layer 408, a liner layer 410, and interconnect layer 412, and a etch stop layer 414. The dielectric layer 406 may be formed of organosilicate glass (SiCOH), silicon dioxide (SiO₂), silicon nitride (Si₃N₄), silicon carbide (SiC), aluminum oxide (Al₂O₃), aluminum nitride (AlN), or any other dielectric material. The barrier layer 408 may be formed of tantalum, tantalum nitride, ruthenium doped tantalum nitride, or any other suitable material. The liner layer 410 may be formed of cobalt, ruthenium, titanium, tantalum, or any other suitable material. The interconnect layer 412, which may be referred to as an m₁ or an m₀ layer, may be formed of molybdenum, tungsten, ruthenium, cobalt, copper, or any other suitable material. The etch stop layer 414 may be formed of silicon nitride, carbon, aluminum oxide (Al₂O₃), or any other suitable material. The second portion 404 may include a dielectric layer 416, a barrier layer 418, and a liner layer 420. The dielectric layer 416 may be formed of organosilicate glass (SiCOH), silicon dioxide (SiO₂), silicon nitride (Si₃N₄), silicon carbide (SiC), aluminum oxide (Al₂O₃), aluminum nitride (AlN), or any other low-k dielectric material. The barrier layer 418 may be formed of tantalum, tantalum nitride, or any other suitable material. The liner layer 420 may be formed of cobalt, ruthenium, titanium, tantalum, or any other suitable material.

In some embodiments, at operation 302 of method 300, the liner layer 420 is deposited over the already formed barrier layer 418 and the patterned dielectric layer 416. The liner layer 420 and barrier layer 418 can be formed by use of a PVD, CVD, ALD, plasma enhanced CVD (PECVD), plasma enhanced ALD (PEALD), or other useful technique. FIG. 4A illustrates an interconnect structure 400 after operation 302 has been performed. In FIG. 4A, the liner layer 420 is disposed over the surface of the barrier layer 418 that is formed on the dielectric layer 414 disposed over the etch stop layer 414. The liner layer 420, the barrier layer 418, the dielectric layer 416, and the etch stop layer 414 each form part of the trench 401 formed in the dielectric layer 416. The dielectric layer 416 is typically disposed on the etch stop layer 414. The etch stop layer 414 is disposed on a dielectric layer 406 disposed within an underlying contact or interconnect structure (e.g., the first portion 402). The dielectric layer 406 may be formed of a dielectric material similar to the dielectric material described above in conjunction with the dielectric layer 416.

In some embodiments, during operation 302, the liner layer 420 is a cobalt containing liner. The liner layer 420 may have a thickness between about 0.1 nm and about 5 nm, such as about 0.2 nm to about 3 nm, such as about 0.5 nm to about 2 nm, such that the liner layer 420 is formed of a conformal layer covering the surface of the barrier layer 418. This thickness may be a minimum thickness to allow for copper reflow, which is discussed below with respect to operation 306. The liner layer 420 may be a pure Co layer that is deposited using an ALD, CVD or PECVD process, such as those described above with respect to FIG. 2.

In some embodiments, the barrier layer 418 may be formed with a thickness of between about 0.2 nm and about 2 nm, such as about 0.5 nm, to about 1.5 nm, such as about 1 nm. The barrier layer 418 may include one or more layers that include a ruthenium (Ru), tantalum (Ta), tantalum nitride (TaN), titanium (Ti), or titanium nitride (TiN) layer, and combinations thereof, that is deposited using PVD, ALD, CVD or PECVD processes, such as those described above with respect to FIG. 2.

In some embodiments, method 300 includes depositing a second liner layer 422 at operation 304. FIG. 4B illustrates an interconnect structure 400 after operation 304 has been performed. In some cases, operation 304 may be performed at or near the same time as operation 302. In FIG. 4B, the second liner layer 422 is disposed at the same time as the liner layer 420, over the surface of the barrier layer 418 that is formed on the dielectric layer 416, disposed over the etch stop layer 414. The second liner layer 422, the liner layer 420, the barrier layer 418, the dielectric layer 416, and the etch stop layer 414 include the trench 401 formed therein.

In some embodiments, the second liner layer 422 may be formed of ruthenium and the liner layer 420 may be formed of cobalt. The second liner layer 422 may have a thickness between about 0.1 nm and about 5 nm, such as about 0.2 nm to about 3 nm, such as about 2 nm. While the liner layer 420 is deposited according to operation 302, the second liner layer 422 may be deposited using a PVD processes, such as those described above with respect to FIG. 1. In some cases, the PVD process is implemented with little or no bias to encourage deposition of the second liner layer 422 with a gradational deposition pattern. Accordingly, the second liner layer 422 is deposited according to a concentration gradient of ruthenium, with more ruthenium material deposited towards the top portion of the trench 401, and less ruthenium material deposited towards the bottom portion of the trench 401, as noted by the change in shading of the second liner layer 422. Some ruthenium material may be deposited on the liner layer 420 at the bottom of the trench 401, but a greater concentration of the ruthenium material will reside at the field and upper portion of the trench 401. It is believed that during the process of depositing the second liner layer 422 the ruthenium deposition will etch at least a portion of the liner layer 420 as it is deposited and form a combined liner layer that includes cobalt and ruthenium, such that liner overhang is not increased towards the top part of the trench 401 and the concentration of the ruthenium material in the combined liner layer is increased. As a result a lower portion of the combined layer includes a ruthenium doped cobalt layer. The resulting ruthenium concentration increases from a lower portion of the trench 401 to an upper portion of the trench 401. Etching may be performed as part of the PVD processes described above, and may be formed by a physical bombardment process and/or a chemical reaction due to the exposure of the cobalt layer found in the liner layer 420 to the deposited ruthenium material. The second liner layer 422 may be considered a sacrificial layer, which may improve gap fill of metal within the trench 401, while reducing overhang and void space. The sacrificial layer may be substantially removed during operation 308.

In some embodiments, method 300 includes depositing a copper layer 424 at operation 306. FIG. 4C illustrates an interconnect structure 400 after operation 306 has been performed. In FIG. 4C, the copper layer 424 is disposed over the second liner layer 422 and the liner layer 420 to substantially fill the trench 401 on the interconnect structures 400. The copper layer 424 may be deposited using a metal deposition process, such as a PVD deposition process. Operation 306 also includes a reflow operation, which can include only partially reflowing the deposited copper layer 424. The reflow process can include heating the substrate 153, which includes the deposited copper layer 424, to a reflow temperature greater than 150° C., such as between about 200° C. and about 600° C., such as about 400° C. in the same chamber as the copper deposition process was performed or in a separate processing chamber within the processing system. The reflow process can include depositing the copper layer 424 while the substrate 153 is heated to the reflow temperature. The reflow process can include depositing copper layer 424 before the substrate 153 is heated to the reflow temperature, then heating the substrate to the reflow temperature. The reflow process can include depositing the copper layer 424. Thus, material forming the copper layer 424 may be heated to a reflow temperature before, during, or after depositing the copper layer.

It is believed that the formation of the second liner layer 422, which includes a concentration gradient of ruthenium within the feature formed on the surface of the substrate 153, improves the results of reflow of the copper layer 424 process by reducing the adhesion of the deposited copper layer to the liner layer 420 and encouraging diffusion of the copper into the lower portions of the trench 401. This is believed to improve the step coverage of the deposited copper layer, reduce the amount of copper overhang after performing the copper deposition process, and minimize the chance of forming voids in the deposited copper containing feature after performing the reflow process as compared to conventional copper deposition, which is typically formed within a feature when the second liner layer 422 is not implemented prior to depositing the copper layer 424. In some cases, this may enhance the strength and reliability of the liner layer 420.

In some embodiments, method 300 includes the subsequent removal of the layers formed on the field region of the substrate during an operation 308. FIG. 4D illustrates an interconnect structure 400 after operation 308 has been performed. After the copper layer 424 is deposited in the trench 401 over the second liner layer 422 and the liner layer 420 at operation 306, the second liner layer 422 of FIGS. 4A-4C is substantially removed along with a portion 426 of the interconnect structures 400. A new surface 428 of interconnect structures 400 is formed by removing a portion 426 of device structure 409. Removing the portion 426 of device structure 409 may include the removal of a portion of the copper liner 424, and the liner layer 420 and barrier layer 418 formed over the field region of the substrate.

In some embodiments, the second liner layer 422 is removed alongside of a portion 426 of the interconnect structures 400 using chemical-mechanical planarization (CMP) processes. CMP processes planarize the surface of the interconnect by applying precise downforce across the backside (not shown) of the interconnect structures 400 and pressing the top of the interconnect structures 400 against a rotating pad of special material that also contains a mixture of chemicals and abrasives.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

While the foregoing is directed to embodiments of the present disclosure, other and further embodiments of the disclosure may be devised without departing from the basic scope thereof, and the scope thereof is determined by the claims that follow.

What is claimed is:

1. A method for forming an interconnect structure, comprising:
depositing a ruthenium layer on a cobalt layer disposed within a feature formed on a substrate, the ruthenium layer having a ruthenium concentration that increases from a lower portion of the feature to an upper portion of the feature; and
depositing a copper layer within the feature, wherein a material forming the copper layer is heated to a reflow temperature before, during, or after depositing the copper layer.

2. The method of claim 1, further comprising depositing the cobalt layer on a barrier layer, the barrier layer being disposed within the feature.

3. The method of claim 2, wherein the cobalt layer comprises a conformal layer covering a surface of the barrier layer.

4. The method of claim 2, wherein the cobalt layer has a thickness of about 0.5 nanometers (nm) to about 3 nm.

5. The method of claim 2, wherein the barrier layer comprises at least one of tantalum, tantalum nitride, and ruthenium.

6. The method of claim 2, wherein the cobalt layer is deposited using chemical layer deposition (CVD) or a plasma enhanced CVD (PECVD) process.

7. The method of claim 1, wherein the ruthenium layer has a thickness of about 0.5 nanometers (nm) to about 5 nm.

8. The method of claim 1, wherein depositing the ruthenium layer further comprises etching at least a portion of the cobalt layer formed in the feature.

9. The method of claim 1, wherein depositing the ruthenium layer is performed using a physical layer deposition (PVD) process, and a ruthenium concentration gradient in the cobalt layer is formed from the top of the feature to the bottom of the feature after depositing the ruthenium layer.

10. The method of claim 1, wherein depositing the ruthenium layer results in a ruthenium doped cobalt layer in at least a portion of the lower portion of the feature.

11. The method of claim 1, wherein depositing the ruthenium layer comprises etching the cobalt layer in the upper portion of the feature.

12. The method of claim 1, wherein depositing the copper layer comprises at least heating the substrate to a temperature greater than 200° C.

13. The method of claim 1, further comprising removing a portion of the interconnect structure, the portion of the interconnect structure comprising an upper portion of the ruthenium layer.

14. The method of claim 13, wherein removing the portion of the interconnect structure is performed using chemical-mechanical planarization (CMP).

15. A method for forming an interconnect structure, comprising:
depositing a cobalt layer on a barrier layer disposed within a feature formed on a substrate;
depositing a ruthenium layer on the cobalt layer disposed within the feature, the ruthenium layer having a ruthenium concentration that increases from a lower portion of the feature to an upper portion of the feature; and
depositing a copper layer within the feature, wherein a material forming the copper layer is heated to a reflow temperature before, during, or after depositing the copper layer.

16. The method of claim 15, wherein depositing the ruthenium layer results in a ruthenium doped cobalt layer in the lower portion of the feature.

17. The method of claim 15, wherein depositing the ruthenium layer further comprises etching at least a portion of the cobalt layer.

18. A method for forming an interconnect structure, comprising:
depositing a ruthenium layer on a cobalt layer disposed within a feature formed on a substrate, the ruthenium layer having a ruthenium concentration that increases from a lower portion of the feature to an upper portion of the feature;
depositing a copper layer within the feature, wherein a material forming the copper layer is heated to a reflow temperature before, during, or after depositing the copper layer; and
removing a top portion of the interconnect structure, the top portion of the interconnect structure comprising a first portion of the ruthenium layer.

19. The method of claim 18, wherein depositing the ruthenium layer results in a ruthenium doped cobalt layer in the lower portion of the feature.

20. The method of claim 18, wherein depositing the ruthenium layer further comprises etching the cobalt layer.
